(19) United States
(12) Patent Application Publication
(10) Pub. No.: US 2026/0134156 A1
(43) Pub. Date: May 14, 2026

(54) METHOD AND SYSTEM FOR ACTION BASED WORKFLOW

(71) Applicant: 3SHAPE A/S, Copenhagen K (DK)

(72) Inventors: Nina Pytter LAURSEN, Copenhagen K (DK); Anders KJÆR-NIELSEN, Copenhagen K (DK); Jesper SIMONSEN, Copenhagen K (DK); Tais CLAUSEN, Copenhagen K (DK); Thomas HEDEGAARD, Copenhagen K (DK); Eskild HANSEN, Copenhagen K (DK)

(73) Assignee: 3SHAPE A/S, Copenhagen K (DK)

(21) Appl. No.: 18/702,130

(22) PCT Filed: Oct. 19, 2022
(86) PCT No.: PCT/EP2022/079029

§ 371 Date: Apr. 17, 2024

(30) Foreign Application Priority Data
Oct. 19, 2021 (DK) PA202170513

(51) Int. Cl. G06F 30/10

(52) U.S. Cl. CPC G06F 30/10

(57) ABSTRACT

A computer-implemented method, a system, and computer readable medium for generating a digital dental workflow. The method includes: receiving a first workflow action selected from a plurality of workflow actions, the first workflow action including an action input; generating an action output at least partly based on the action input of the first workflow action; suggesting at least a second workflow action and a third workflow action from the plurality of workflow actions based on the action output generated by the first workflow action, wherein at least a part of the action output of the first workflow action at least partly represents an action input for each of the at least the second workflow action and the third workflow action; and generating the digital dental workflow upon a selection of the at least the second workflow action or the third workflow action.

### FIELD OF DISCLOSURE

The present disclosure relates to a method and system for action based workflow and more particularly to a method and system for dynamically generating a digital dental flow comprising at least two workflows.

### BACKGROUND DISCUSSION

In the analog world of dental restorative and orthodontic work dentists usually starts by creating a treatment plan after an initial clinic visit where the patient gives consent to a dental treatment process. The treatment plan can include the various manufacturing and delivery details of the desired dental component such as a crown. The initial visit is followed by a second clinical visit where the dentist may perform a physical intervention (e.g. tooth preparation) to the patients dentition and taking a physical impression of the dentition intended for the manufacturing process of the desired dental component (e.g. crown restoration). The treatment plan is then finished by suppling any additional details and instructions to the order and sending the additional details and instructions to a dental laboratory for design and manufacturing.

With the arrival of digital dentistry, this process had been significantly improved in terms of speed, accuracy, and comfort of the patient, as three-dimensional (3D) scanning of a patient dentition enables the opportunity of computer-aided design and manufacturing (CAD/CAM). Despite that much of the paperwork related to preparing a treatment plan is replaced by a digital file which may easily be send and shared, the individual steps of preparing the order form remains essentially the same as in the analog scenario. Generally, in the field, the digital order form is a graphical user interface presenting an overview of different type of dental components from which a dental component may be chosen as an end goal for a patient treatment. The order form will display a variety of options for the dentist to choose from in order to construct the treatment plan corresponding to the treatment that the dentist and the patient has agreed to perform. The dentist is prompted to provide material choice and shade for manufacturing upfront depending on the specification selected in the order form. Based on the user input, the software will provide a so-called pre-set “workflow” to accomplish that particular choice of end goal. A pre-set workflow is a fixed (i.e., static) sequence of actions which need to be fulfilled in order to provide the system with the correct information to meet the treatment goal.

For example, a workflow for a crown restoration could include:
Dentist identifies a patient
Choose whether the dental component should be performed in-house or by a specific a dental laboratory
Specify the tooth which needs a restorative treatment
Pick the restoration type (crown)-material choice and perhaps shading
Specify the delivery date of the restoration
Write instructions to a dental laboratory
Based on the selection the user will be guided through a sequence of additional steps, which can include directed to the dentist to a “scan page” and guiding the dentist through a “pre-prep scan”:
   scan upper jaw,
   scan lower jaw
   scan bite
Dentist prepares the damage tooth by drilling most of the enamel away to create a tooth-prep
Rescanning the patient focused on the prepared tooth
Adding details to the scan, which can include:
   Measure and capture tooth shade information
   Add comments about e.g. the margin line
sending the 3D model(s) of the patients dentition to a dental lab to manufacture the crown following the specification
Communicating with the lab afterwards, if there are any questions or if the necessary details were not captured during scanning

The current state of the digital order form is thus a digitalization of the analog process which demands that the user know exactly what the end goal is, including many manufacturing details like material choices or shadings. Additionally the dentist may be forced to spend time addressing the manufacturing details while the patient is sitting in the dental chair awaiting the dentist to perform the necessary actions. Unexpected situations may occur when the dentist starts the treatment and prepares a tooth, the dentist may get surprised by something (for example, condition of the tooth is worse, and needs a crown instead of a veneer or needs a more durable material e.g.), or the shade measurement by the scanner makes the dentist want to change the initial set shade. The dentist will ask the patient to accept the change, since some of these changes will increase the initially agreed price. These change may require that the dentist go all the way back to the order form, make changes, maybe change the dental laboratory, and the software for the digital order cannot always handle the changes, and the scan may get lost or may even need to perform multiple slightly different workflow including duplication of scan data.

### SUMMARY

It would be desirable to have a method and system for an action based workflow architecture that divides the treatment plan into two or more sequences, for example, a data acquisition sequence and a computer-aided design and computer-aided manufacturing (CAD/CAM) sequence, which can decreases the time the patient will spend in the dental chair during a clinical visit. In accordance with an exemplary embodiment, the action based workflow architecture can include a plurality of workflow actions, and wherein each of the workflow actions includes an action input and an action output that is usually generated based on the action input. Each workflow action may include a set of steps or options which utilizes the action input in order to generate the action output. For example, the action input for a treatment simulation workflow action may include a 3D digital model of patient teeth representing actual teeth arrangement, and the action output may include a 3D digital model of patient teeth in a simulated teeth arrangement representing a potential outcome of a dental treatment. The treatment simulation workflow action typically includes steps or options such as segmentation of 3D digital model of patient teeth in actual teeth arrangement into individual dental objects, steps for manual or at least partially automatic way of rearranging the teeth in the simulated teeth arrangement. In another example, the action input may simply include patient information such as age, demographics, tooth shade data, etc. that may be utilized in one or more steps of the workflow action to

### Generate The Action Output

In accordance with an aspect, a computer-implemented method for generating a digital dental workflow, the method comprising: receiving a first workflow action selected from a plurality of workflow actions, the first workflow action including an action input; generating an action output at least partly based on the action input of the first workflow action; suggesting at least a second workflow action and a third workflow action from the plurality of workflow actions based on the action output generated by the first workflow action, wherein at least a part of the action output of the first workflow action at least partly represents an action input for each of the at least the second workflow action and the third workflow action; and generating the digital dental workflow upon a selection of the at least the second workflow action or the third workflow action, and wherein the generated digital dental workflow comprises the first workflow and the selected at least the second workflow action or third workflow action.

In accordance with a further aspect, suggesting at least the second workflow action and the third workflow action is based on determining, among the plurality of workflow actions, workflow actions (e.g. second and third workflow actions) requiring action input that is same as the action output of the first workflow action. The determination may be implemented in different ways. The determination may include identifying the action output of the first workflow action and identifying the workflow actions based on the identified action output. The action output may be identified by analysing the action output of the first workflow action such as by performing an image analysis of the action output and/or identifying the action output simply based on prior knowledge about the action output of the first workflow action, such as based on a look up table comprising action output for different workflow actions. Once the action output is identified, the second workflow action and third workflow action may be identified in a few ways, for example using a neural network that is trained to identify workflow actions that is configured to utilize the action output of the first workflow action as action input. Another way to identify workflow actions is by performing a search for the identified action output of the first workflow action in a look up table that comprises workflow actions with corresponding required action input. Once the search, using the action output of the first workflow action as action input search parameter, is performed, the search result may be suggested as the workflow actions (e.g. second and third workflow actions) that require action input that is the action output of the first workflow action, for example as selectable options on a user interface.

In accordance with another aspect, a system for assisting a dental professional in a dental evaluation or treatment of a patient, wherein the system comprises: a computer system comprising a processor and a computer readable medium comprising executable instructions, which when executed by the processor: receive a first workflow action selected from a plurality of workflow actions, the first workflow action including an action input; generate an action output at least partly based on the action input of the first workflow action; suggest at least a second workflow action and a third workflow action from the plurality of workflow actions based on the action output generated by the first workflow action, wherein at least a part of the action output of the first workflow action at least partly represents an action input for each of the at least the second workflow action and the third workflow action; and generate the digital dental workflow upon a selection of the at least the second workflow action or the third workflow action, and wherein the generated digital dental workflow comprises the first workflow and the selected at least the second workflow action or third workflow action.

In accordance with an aspect, a system for assisting a dental professional in a dental evaluation or treatment of a patient, wherein the system comprises: an intra oral scanner; and a computer system in communication with the intra oral scanner for generating a digital dental workflow, the computer system include a processor configured to: receive a first workflow action selected from a plurality of workflow actions, the first workflow action including an action input; generate an action output from the action input of the first workflow action; suggest at least a second workflow action and a third workflow action from the plurality of workflow actions based on the action output generated by the first workflow action, wherein at least a part of the action output of the first workflow action includes an action input for each of the at least the second workflow action and the third workflow action; and generate the digital dental workflow upon a selection of the at least the second workflow action or the third workflow action.

In accordance with a further aspect, a computer program product embodied in a non-transitory computer readable medium, the computer program product comprising computer readable program code being executable by a hardware data processor to cause the hardware data processor to provide instructions for generating a digital dental workflow, the instructions comprising: receiving a first workflow action selected from a plurality of workflow actions, the first workflow action including an action input; generating an action output at least partly based on the action input of the first workflow action; suggesting at least a second workflow action and a third workflow action from the plurality of workflow actions based on the action output generated by the first workflow action, wherein at least a part of the action output of the first workflow action at least partly represents an action input for each of the at least the second workflow action and the third workflow action; and generating the digital dental workflow upon a selection of the at least the second workflow action or the third workflow action, and wherein the generated digital dental workflow comprises the first workflow and the selected at least the second workflow action or third workflow action.

### BRIEF DESCRIPTION OF THE DRAWINGS

FIG. 1 is an illustration of a system for generating a digital dental workflow in accordance with an exemplary embodiment.

FIG. 2 is an illustration of a plurality of workflows for generating a digital dental workflow in accordance with an exemplary embodiment.

FIG. 3 is an illustration of a plurality of workflows for generating a digital dental workflow starting with a scan at a first patient visit in accordance with an exemplary embodiment.

FIGS. 4-9 are illustrations of graphical user interfaces for a first visit of a patient in accordance with a digital dental workflow in accordance with an exemplary embodiment.

FIGS. 10-15 are illustrations of graphical user interfaces for a second visit of the patient in accordance with the digital dental workflow in accordance with an exemplary embodiment.

FIG. 16 is a flowchart illustrating a computer-implemented method for generating a digital dental workflow in accordance with an exemplary embodiment.

FIG. 17 is an exemplary hardware architecture for an embodiment of a computer device in accordance with an exemplary embodiment.

### DETAILED DESCRIPTION

Set forth below with reference to the accompanying drawings is a detailed description of embodiments of a method and system for action based workflow. Note that since embodiments described below are preferred specific examples of the present disclosure, although various technically preferable limitations are given, the scope of the present disclosure is not limited to the embodiments unless otherwise specified in the following descriptions.

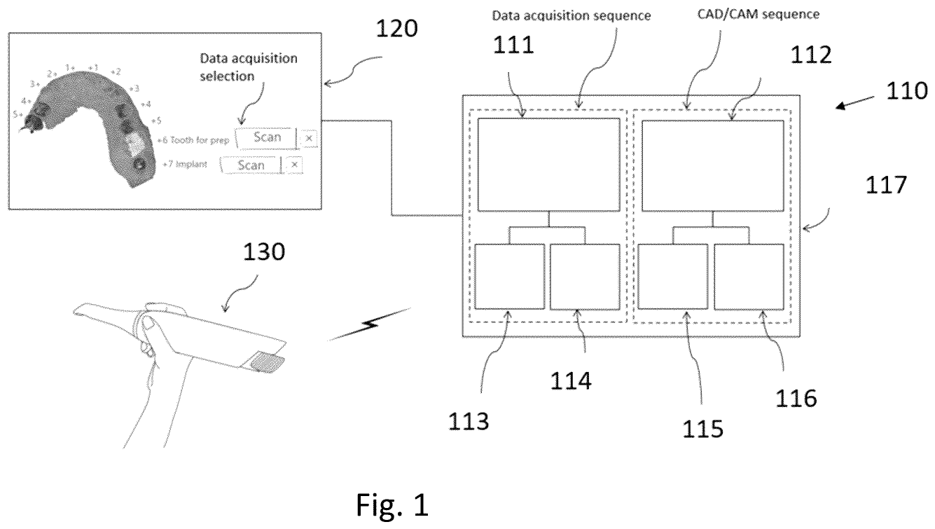

FIG. 1 is an illustration of a system for generating a digital dental workflow in accordance with an exemplary embodiment. As shown in FIG. 1, the system 100 can include a computer device 110 comprising a data acquisition module 111, a design and manufacturing module 112, a scanning module 113, a patient library 114, a computer-aided manufacturing (CAM) module 115, and a dental laboratory connection module 116. In accordance with an exemplary embodiment, the data acquisition module 111, the scanning module 113, and the patient library 114 comprises a data acquisition sequence, and the design and manufacturing module 112, the computer-aided manufacturing (CAM) module 115, and the lab connection module 116 comprises a computer-aided design and computer-aided manufacturing (CAD/CAM) sequence. The data acquisition module 111, the design and manufacturing module 112, the scanning module 113, the patient library 114, the computer-aided manufacturing (CAM) module 115, and the lab connection module 116 comprises a software platform 117.

In accordance with an exemplary embodiment, the system further comprises a visual display unit or user interface 120 with an optional computer keyboard and computer mouse for entering data and activating virtual buttons visualized on the visual display unit or user interface 120. The visual display unit or user interface 120 can be a computer screen.

In addition, a method and system is disclosed that by requesting as little information as possible at the time of the initial visit by the patient, remove complexities that may delay the patient visit can be removed. For example, the method and system can include a dynamic software module that control the data acquisition sequence enabling the dentist to rather easily acquire the right (and enough) data from the patient without any duplication or insufficient work even while maintaining full flexibility of treatment outcome. In addition, this can help enable the dentist to be more time efficient and decrease the discomfort of the patient, as chair time is typically associated with a necessity rather than being enjoyable.

In accordance with an exemplary embodiment, the data acquisition module 111 can help enable the dentist to select the patient profile in the user interface 120 as the only initialization requirement wherein as the user is guided into a start page enabling the opportunity to either import a 3D virtual model or start a new scanning. Based on the initial 3D virtual model the 3D information is processed and based on the processed data a number of subsequent data acquisition suggestions are presented. The data processing may be, for example, in the form of semantic segmentation of the 3D vertical model into separate dental sites, which can be done to identify individual teeth, gingiva, preparations, implants, scan flags, etc. The data acquisition module 111 may also provide the user with suggestions to additional data acquisition based on a combination of trained machine learning algorithms and heuristics. One example could be the identification of a prepared tooth which may trigger a suggestion to perform local detailed tooth-prep scan data. Alternatively, the user may manually select a dental site and choose to perform an additional action, such as obtain information associated with a particular treatment intended for of a particular dental site. In addition, to being able to process new scan data, the data acquisition module 111 may be able to access all historical data from that particular patient accessible by the system. Such historical data may be in the form of previous 3D data, 2D photos, X-ray images, CBCT data or any other modality in the process. The data acquisition module 111 may prompt the user to perform all relevant actions associated with obtaining the necessary image data before allowing the user to exit the data acquisition sequence and inter the CAD/CAM sequence.

In accordance with an exemplary embodiment, the CAD/CAM sequence allows the user to utilize the recorded data in the design and manufacturing step, which can be accomplished as a later point in time, when the patient is no longer in the clinic or are in a more comfortable position. The design and manufacturing module 112 can also allow the user to specify all desired dental components needed for a particular treatment either by specifying manufacturing details and sending it to a lab or by performing the design local in the clinic or even a combination of sending part of the work to a lab (or to several labs), and designing locally in the clinic for some of work.

In accordance with an exemplary embodiment, the method and system as disclosed herein can be used with the designing of a virtual 3D model such that a dental restoration manufactured from the virtual 3D model can be inserted at a target site of a patient's set of teeth. The may include identifying a margin line, determining an insertion direction corresponding to insertion of a physical crown towards the prepared tooth, desigining the restoration based on the identified margin line and determined insertion direction. The designing may further include determining collision of designed restoration in relation to teeth neighboring to and/or opposed to the prepared tooth, and modifying the designed restoration to avoid the collision. These options, for example, can be presented in a virtual environment visualized on the visual display unit or user interface 120. The system 100 is also configured to transmit the final 3D arrangement of the patient's teeth after transformations to, for example, a computer-aided manufacturing (CAM) device for manufacturing, for example, a crown, to another computer system, for example, located at a milling center where the crown can be manufactured. The unit for transmitting can be a wired or a wireless connection. The 3D scanning of the patient's upper and lower jaw using the 3D scanning device 130 can be performed at a dentist while creating the crown at a dental laboratory. In such cases the digital 3D representation of the patient's upper and lower jaw can be provided via an internet connection between the dentist and the dental laboratory.

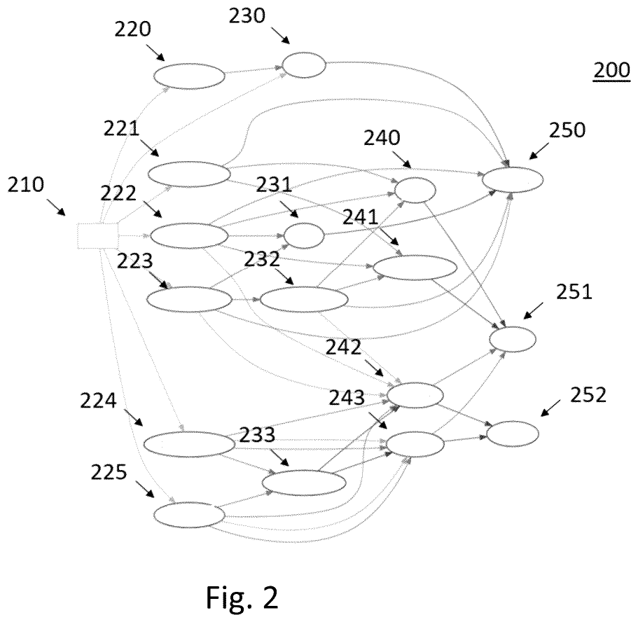

FIG. 2 is an illustration of a plurality of workflows 200 for generating a digital dental workflow in accordance with an exemplary embodiment. The method and system as disclosed for generating a digital dental workflow by splitting previously established workflows into smaller pieces, for example, by separate scanning from the other workflows in the digital dental workflow. For example, the process starts at 210 in which the dentist does not have any data on a patient. As shown in FIG. 2, for example, one or more of the following first workflows can be performed: a scanning action 220, comprising scanning a dental object or a gypsum model; an intra oral scanning action 221, 223, 224, 232, comprising scanning directly in an oral cavity of a patient; a model retrieval action 222, comprising selecting and retrieving a stored 3D model from a database; a record population action 224, 225 comprising populating a digital patient record with new or updated information. In accordance with exemplary embodiment, the intra oral scanning action 221, 223, 224, 232, and the record population action 224, 225 comprising populating a digital patient record with new or updated information can include for example, X-ray scanning, such as Computed Tomography (CT) X-ray or Cone beam CT (CBCT) scanning, and/or TRIOS intra-oral scanner manufactured by 3shape TRIOS A/S, or capable of receiving scan data from such a 3D scanning device and forming a digital 3D representation of the patient's set of teeth based on such scan data.

In accordance with an exemplary embodiment, the at least second workflow action or the third workflow action can include, for example, an order form action 230, comprising selecting a specific type of treatment for a patient, such as dental restoration to be performed such as a crown, bridge, implant, etc., or for example, a type of treatment via a 3^{rd} party application 250; or a patient monitoring action 231, 233 comprising comparing at least two dental scans taken at different times.

In accordance with an exemplary embodiment, the at least the second workflow action or the third workflow action can include a restorative action 241, comprising performing a digital design of at least one dental prosthesis; a treatment planning action 242, comprising generating at least one orthodontic target design of the jaws of a patient; and/or a patient excitement action 243, comprising generating at least one digital image of an expected target oral situation of a patient.

In addition, the workflow actions can include a practice management action 251, comprising sharing, managing and maintaining patent related administrative tasks between software systems; and an analyzer action 252, comprising analyzing the 3D scan of the oral cavity in relation to different dental parameters.

For example, one digital dental workflow could include a clinic doing in-house design and production of crowns. In accordance with an exemplary embodiment, by separating the design and production of crowns into workflows that include a first workflow, for example, a scan acquisition, and a second workflow, for example, design and manufacturing of the crown, a system and method is disclosed that allows the user performing the scan to focus on and complete the scan with the patient in the chair. In addition, by separating the digital design workflow into a first workflow and a second workflow, this allows the dentist, for example, to rather easily change the design and/or manufacturing process, for example, if it is determined that the crown cannot be produced in-house and must be sent to external manufacturing at a dental laboratory (due to lack of time or competences).

In addition, the splitting of workflows into smaller workflows can also enable 3rd party integrations to rather easily build upon workflows (e.g., scanning), for example, using a scanning workflow, which data can be later accessed when needed. In accordance with an exemplary embodiment, it would be desirable to build a framework where it is the responsibility of the follow-up workflows, to describe dependencies of the prior workflows, and where the framework only needs to know about the prior workflows (e.g., action output from prior workflows or immediately prior workflow), and the system and method provides the connections between workflows, and which can be rather easily scaled without complex central knowledge of all the potential combinations.

In accordance with an exemplary embodiment, the system and method for generating a digital dental workflow can include workflows that have dependency-descriptions and the workflows can therefore be built with an explicit graph of possibilities allowing the system and method to present the user with potential next steps (e.g., subsequent workflow actions). For example, the method and system can include one or more options including evaluate at least action input requirement of the workflow to follow up, use high level workflow identifiers describing the workflow and follow up, which can include, for example, a predetermined sequence of workflow actions arranged in an order format such as “Status Scan”, which can include the scanning of the upper jaw with scanning of the lower jaw and bite scan of the upper jaw and lower jaw. In accordance with an exemplary embodiment, the at least second workflow action and the third workflow action can use the action output from the first workflow action as the action input for the second workflow action and the third workflow action. Alternatively, a more fine-grained version of the high level workflow identifiers that introduce workflows that can consist of several sub flows, for example, each of which can be followed up. For example, a sub flow could include just a scan of an upper jaw, which can be treated as workflow action with the scan data as the action input and the 3D model of the upper jaw being an output action.

In accordance with an example, a single-dependency digital dental workflow can include second-or third workflow action like for example, an in-house crown design, or ordering a restoration from the a dental laboratory. The single-dependency digital dental workflows only requires an single action output from a first scanning workflow action., Another example using the same workflow action output (e.g., a 3D model from a scanning action) for input to multiple follow up workflow actions, which make uses of a single dependency, such that the initial workflow action output is utilized as input for a fourth or fifth workflow action which is independent of each other. However, in accordance with an exemplary embodiment, through the use of a plurality of workflows as disclosed herein, the system and method can enable the user to have follow-up workflows (e.g., a sixth or seventh workflow actions) that requires multiple dependencies (e.g., requires two or more action outputs) that need to be met for the user to continue with the one or more of those workflows. For example, with a patient media library, several modalities can be selected that enable certain follow-up workflow action, e.g., implants, for example, an implant studio action being available if a surface scan (e.g., first action output) and, for example, a cone beam computed tomography (CBCT) scan (second action output) is selected. In addition, multi-dependency descriptions can also allow user to declare, for example, a dentist may have directed their attention to do implant planning action and maybe even surgical guide action, and the method and system as disclosed herein can inform the user that the implant planning action has two action output pre-requisites, for example, a surface scan and a CBCT scan. If none of these are available for the patient, the user can be instructed to first complete the surface scan and the CBCT scan before generating the digital dental workflow.

In accordance with an exemplary embodiment, example of the generation of a digital dental workflow as disclosed herein can include, for example, one or more of the following:

### Example #1

A patient is entering a clinic with a problem with one incisor. If the correct treatment should be a crown or a veneer is unclear before prepping the tooth is initiated. The action based workflow allows the dentist to postpone the decision within the software until the appropriate time.

### Example #2

A patient needs two restorations done, for example, one molar which should be an in-house fabrication and one pre-molar which need to be made by a lab for aesthetic reasons. The dentist may first agree with the patient that both teeth should be made with Emax. During treatment and preparation, the dentist realizes that there is probably a need for a higher level of aesthetics, and suggests the patient to make one of the restoration in a different material, and with a different production method (stained and glazed). The dentist must agree on a new price with the patient, change the restoration parameters, and may need to send the order to a different dental laboratories (because the other lab mostly does Emax molars)

### Example #3

Selecting one or more modalities in the patient media library, can also enable the user to start follow up flows using the selection including send-to-lab requests.

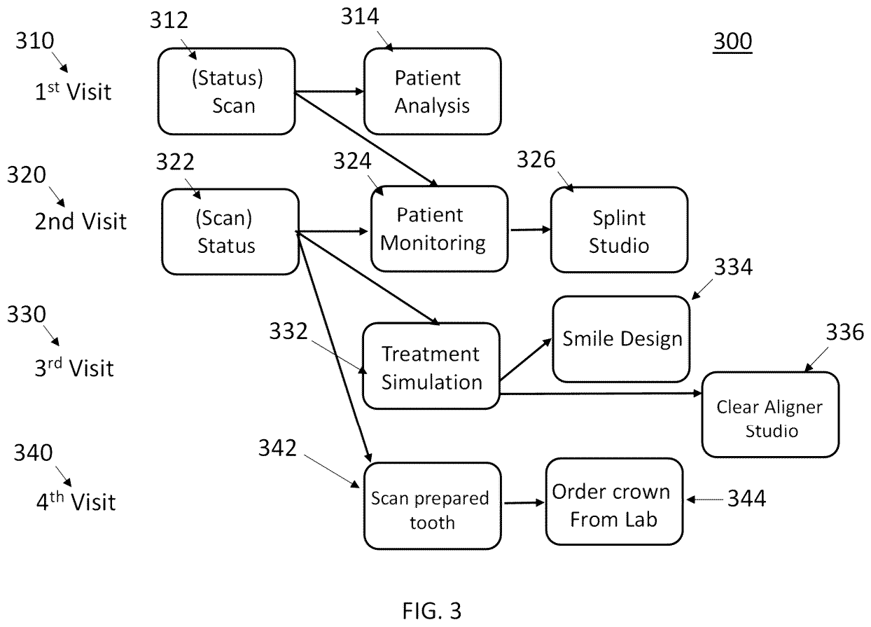

FIG. 3 is an illustration of a plurality of workflow actions for generating a digital dental workflow where each box (e.g. 312, 322, 314, 324, and so on) representing a workflow action. The direction of the representing arrow is directed towards suggested workflow actions corresponding to prior workflow action, the action output of which may be used as action input for the suggested workflow actions. For example, for the first workflow action 322, the suggested workflow actions include a second workflow action 324, third workflow action 332 and fourth workflow action 342. The action output from 322 may be used as an action input in any of the 324, 332, and 342. Depending upon the selection (e.g. 332) among the suggested workflow actions, the digital dental workflow is dynamically generated and may be further generated if a further subsequent workflow action (e.g., 336 ) is selected from further suggested workflow actions (e.g., 334, 336). In accordance with an embodiment, as shown in FIG. 3, the process starts with a first patient visit 10, in which a first workflow action in the form of a scanning action 312 can be performed on the patient. On the first visit, in a step 314, which can be, for example, considered a second workflow action, an analysis of the patient can be performed, which can include in the data obtained from the scan, such as an caries inspection analysis based on the obtained data from the scan such as infra-red data or fluorescence data.

In accordance with an exemplary embodiment, on a second visit 320, a second scan, which can be a similar scan (e.g. scan of the same dental object such as intraoral cavity as the first scan but at different time point or different types e.g. different type of texture scan such as color or fluorescence scan) or a different scan (scan of different at least partly different dental object such as intraoral object but related e.g. full jaw scan and scan of preparation site), for example can be performed in a step 322. In addition, the second visit can include patient monitoring, and, for example, a referral, of the patient for a single-jaw occlusal splint, for example, via Splint Studio from 3 shape A/S as an additional workflow action.

In accordance with an exemplary embodiment, on a third visit 330, following the second status 320, a treatment simulation 332 or a scanned prepared tooth 342 can be prepared, for example, on a fourth visit 340. In addition, the third or fourth visits 330, 340 can include IvoSmile Smile design from Ivoclar Vivadent AG, a Clear Aligner Studio 336 from 3 Shape A/S, or order crown from a laboratory 344. It can be appreciated that some of the workflow actions that are shown in relation to the later visits may even be available at the previous visit so long as the action output of the prior workflow action is suitable to be used in the subsequent workflow action. For example, workflow action 332 may be available in 1^{st} visit and 2^{nd} visit, as is also illustrated by the arrow connecting 322 with 332 and 342.

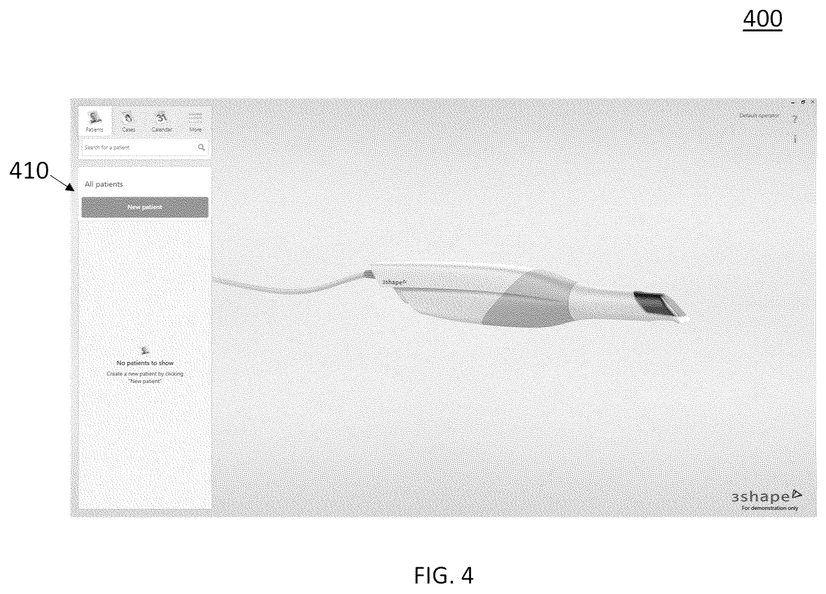

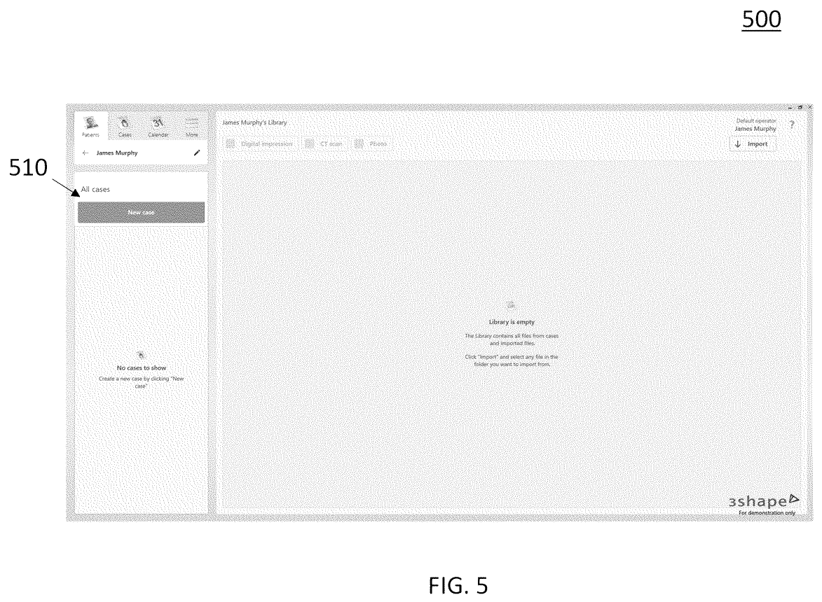

FIGS. 4-9 are illustrations of graphical user interfaces for a first visit of a patient in accordance with a digital dental workflow in accordance with an exemplary embodiment. As shown in FIG. 4, during the first visit of a patient with a dentist, the dentist can be presented with a start page 400, which includes, for example, a “New Patient” link 410. Once the “New Patient” link has been clicked, the process can move to a second user interface page 500, in which a library of scans and other related data for the patient is displayed. However, since the patient is a new patient, the library of scans and other related data will be empty. In addition, once the patient has been created, the user, for example, can be presented with a “New case” link 510.

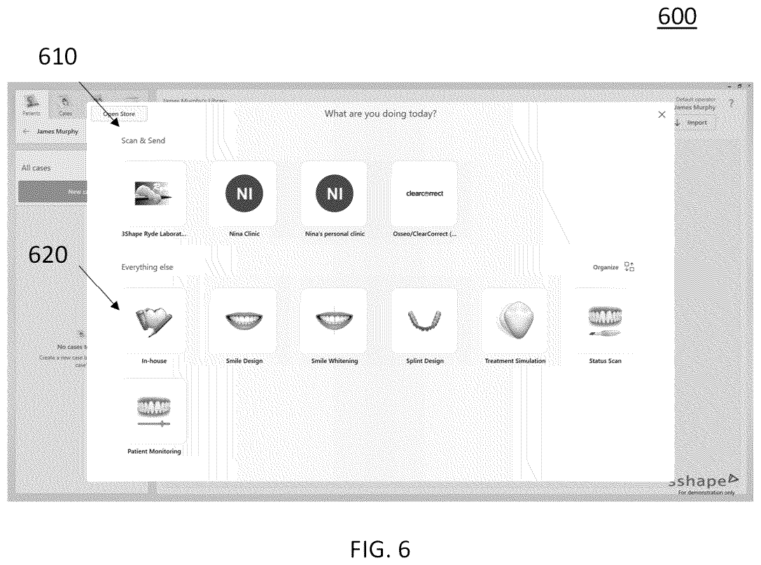

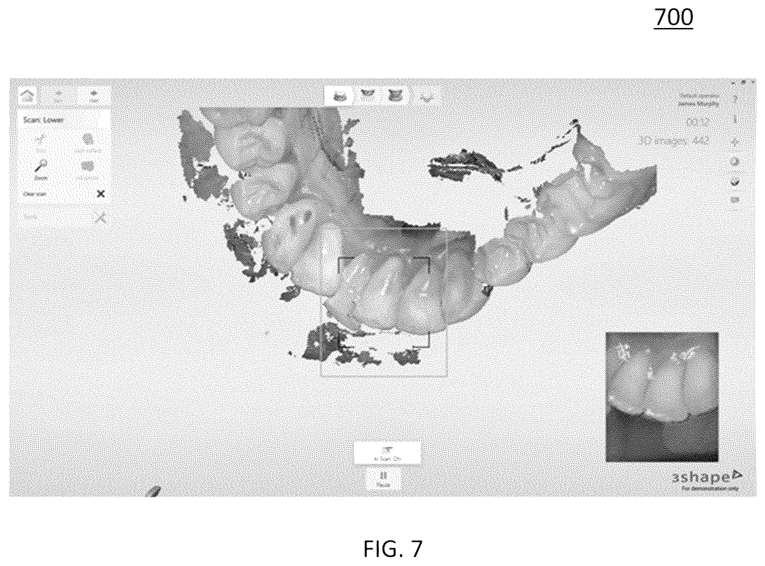

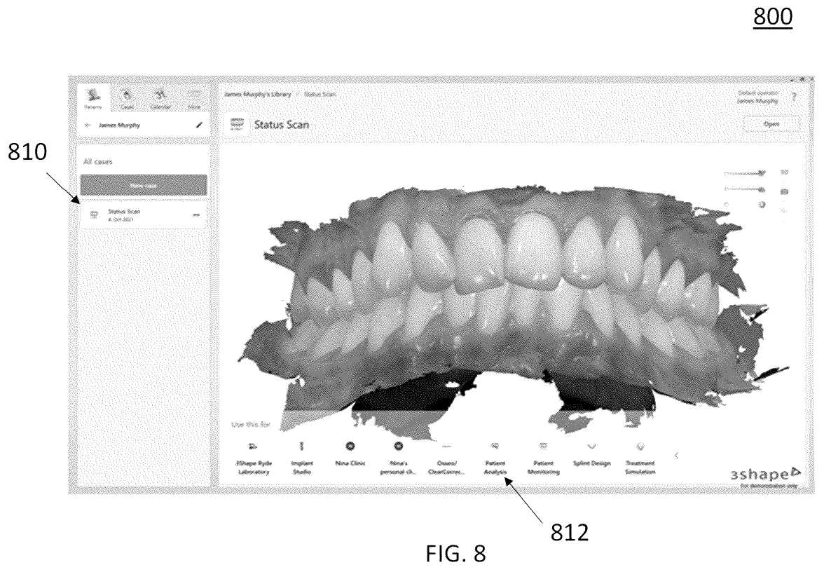

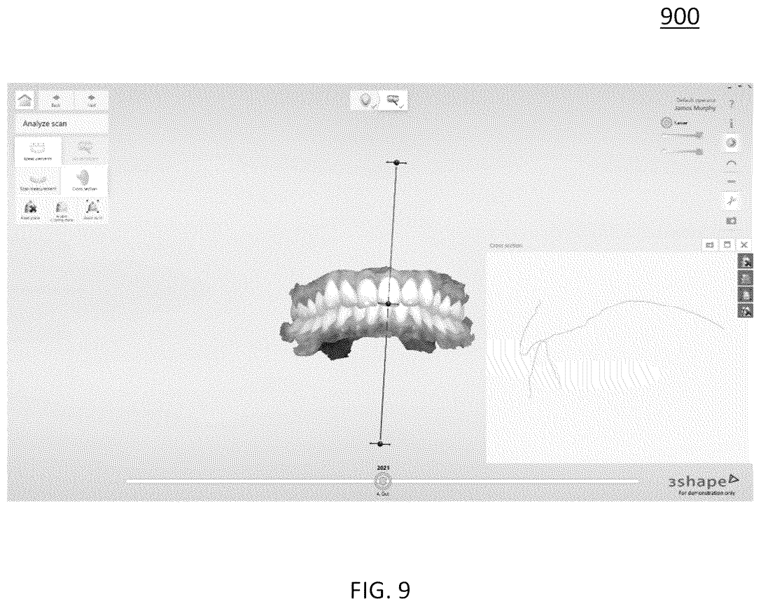

As shown in FIG. 6, the user can click the “New case” link 510, and a corresponding a pop-up window 600 can be presented with a plurality of workflow actions in which the user can select a first workflow action. For example, the plurality of workflow actions as described herein can displayed on the graphical user interface including, for example, scan and send options 610, e.g., third party providers, or alternatively, other options for other workflow actions 620, which can include, for example, an “In-house” option, “Smile Design”, “Smile Whitening”, “Splint Design”, “Treatment Simulation”, “Status Scan”, or “Patient Monitoring”. As shown for example, in FIG. 7, upon selection of the first workflow action, for example, of the “Status Scan”, a 3D model 700 of the teeth of the patient can be obtained, such as at the first patient visit (e.g. 310, FIG. 3). FIG. 8 illustrates a follow up on the scan 810 obtained in FIG. 7 upon the selection, for example, of “Patient Analysis action” 812 on the graphical user interface 800. FIG. 9 illustrates an analysis 900 of the cross-section obtained from the patient analysis action selected in FIG. 8. In relation to the disclosed embodiment, the generated digital dental workflow comprises the Status Scan action of FIG. 7 and FIG. 8 and Patient Analysis action of FIG. 9, where the action output i.e. generated 3D model of FIG. 8 is used as an action input for workflow action of Patient Analysis workflow action 812.

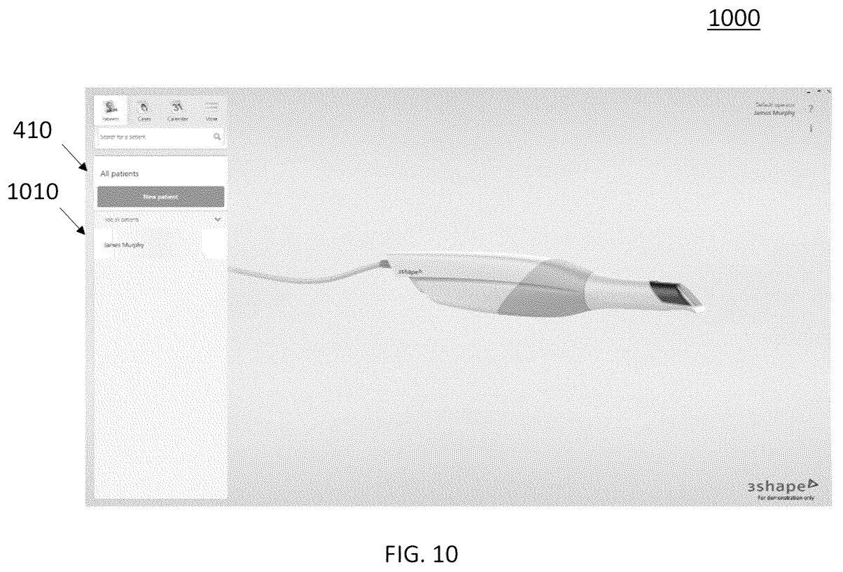

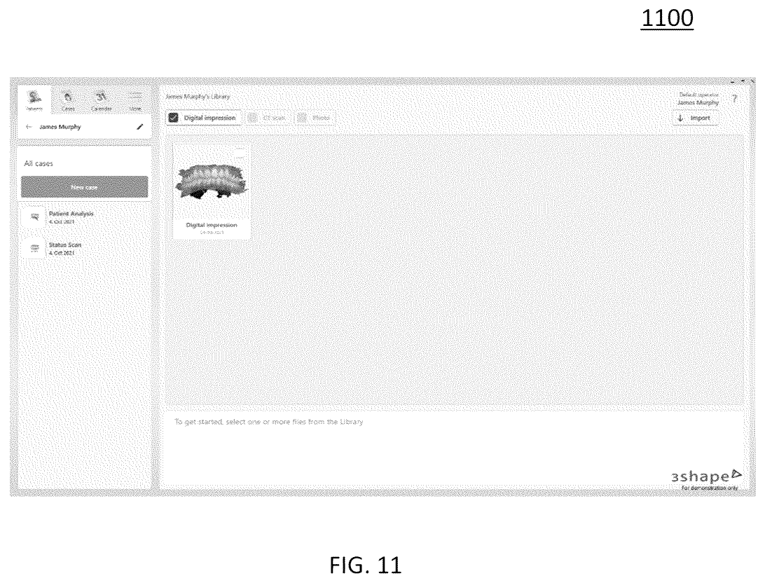

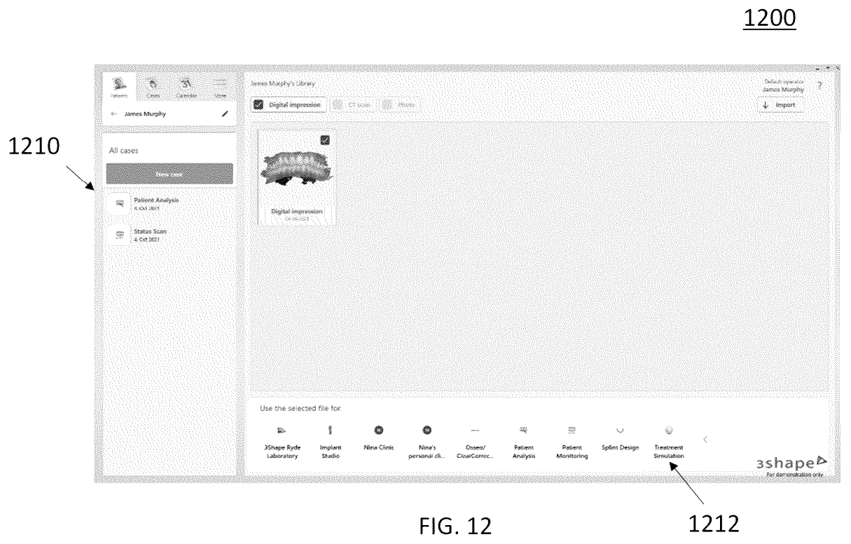

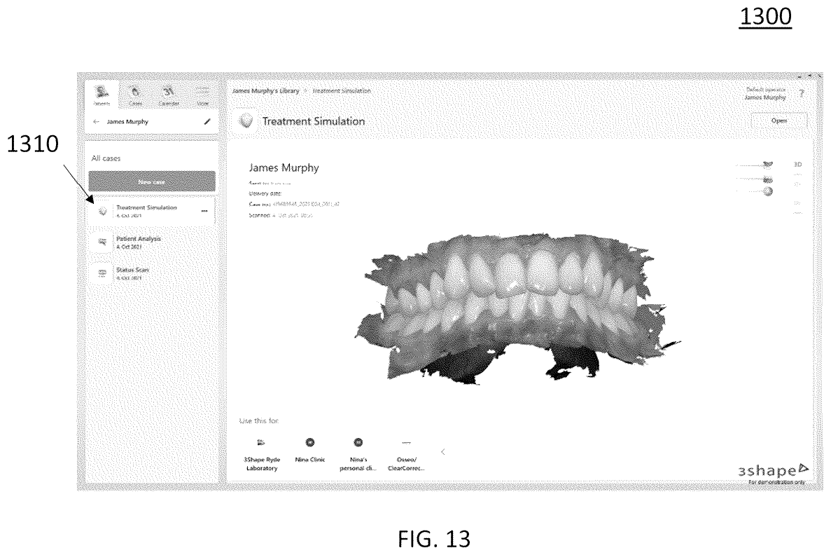

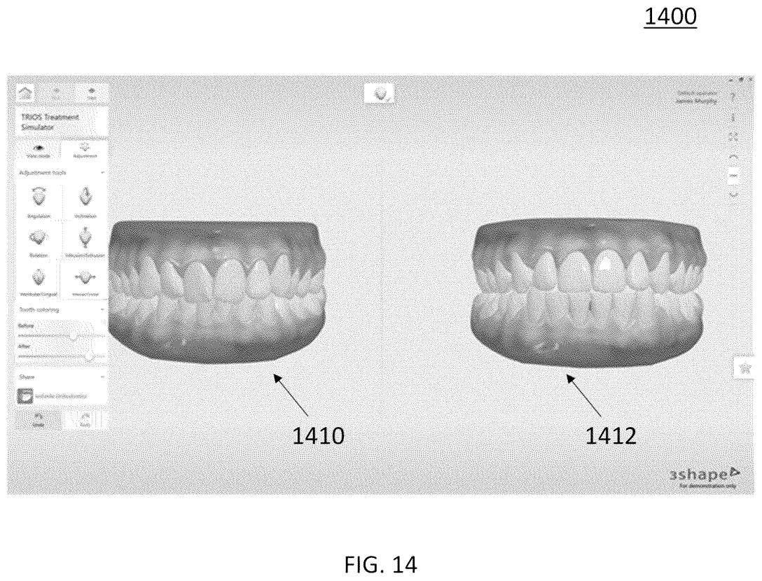

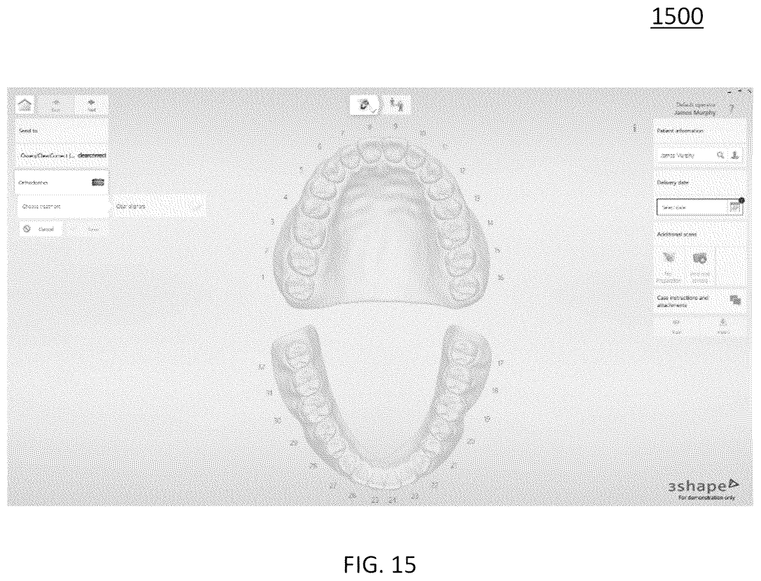

FIGS. 10-15 are illustrations of graphical user interfaces for a second visit of the patient in accordance with the digital dental workflow in accordance with an exemplary embodiment. As shown in FIG. 10, during the second visit such as at 322 FIG. 3 of the patient with the dentist, the graphical user interface displays the start page 1000, which includes the “New Patient” link 410 but also a link to one or more patients 1010 that have been previously entered into the system. Once the “one or more patients” link 1010 has been clicked, the process can move to the second user interface page 1100, in which a library of scans and other related data for the selected one or more patients 1010 are displayed. As shown in FIG. 12, a selection of Patient Analysis 1210 or Treatment Simulation 1212 can be selected by the user, for example, from a plurality of workflow actions that are available based on the available data on the one or more patients. In FIG. 13, illustrates a user interface 1300 for simulating an orthodontic treatment via a selection of a treatment simulation link 1310. In FIG. 14, a user interface illustrating where treatment simulation 1400 that is configured to digitally simulate 1412 dental treatment on patient data 1410 can be shown. In FIG. 15, the user can be presented with an order form 1500 that provides for clear aligners to be ordered from a third party such as a clear aligner manufacturer.

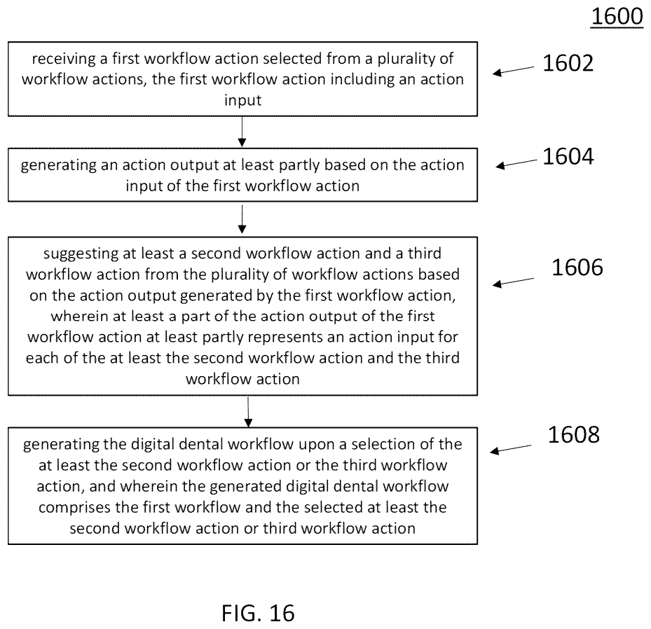

FIG. 16 is a flowchart illustrating a method 1600 for a computer-implemented method for generating a digital dental workflow. As shown, the method 1600 includes in step 1602, receiving a first workflow action selected from a plurality of workflow actions, the first workflow action including an action input. In step 1604, an action output is generated at least partly based on the action input of the first workflow action. In step 1606, at least a second workflow action and a third workflow action from the plurality of workflow actions is suggested based on the action output generated by the first workflow action, wherein at least a part of the action output of the first workflow action at least partly represents an action input for each of the at least the second workflow action and the third workflow action. In step 1608, the digital dental workflow is generated upon a selection of the at least the second workflow action or the third workflow action, and wherein the generated digital dental workflow comprises the first workflow and the selected at least the second workflow action or third workflow action.

In accordance with an exemplary embodiment, the method can further include obtaining a first intra oral scan of an oral cavity of a patient as action input for the first workflow action, generating a three-dimensional (3D) scan of the oral cavity of the patient from the intra oral scan as the action output from the action input of the first workflow action, or selecting and retrieving a stored previously generated model, and suggesting a predefined workflow as the at least the second workflow action and the third workflow action. In addition, for example, after the selecting of the the at least the second workflow action or the third workflow action is suggested, at least another workflow action for one second intra oral scan of the oral cavity as action input for generating a second 3D scan of the oral cavity of the patient, and digitally designing a dental prosthesis based on the second 3D scan may be suggested.

For example, in accordance with an exemplary embodiment, the first workflow action can be scanning where the action input is “scan data” and action output is “segmented data set”, which is a 3D model with a semantic segmentation applied to it for recognizing different aspects of the 3D model, like a prepared tooth, an implant, etc. The suggested second workflow action or third workflow action may include workflows that include advanced automatic artificial intelligence (Al)/machine learning based analysis and design such as second workflow action may perform a crown design on a recognized prep-site (for example, a detailed prep-site scanning) and third workflow action may include placing an abutment on the recognized implant (for example, an additional scan with a scan-post attached to the implant to determine the model and orientation). Alternatively, the suggested second workflow action or third workflow action could be to “identify patient” based on the 3D model or segmented 3D model (use the 3D data to search the database and automatically associate the new data with the correct patient).

In accordance with an exemplary embodiment, the plurality of workflow actions are chosen from a group consisting of: a scanning action, comprising scanning a dental object or a gypsum model; an intra oral scanning action, comprising scanning directly in an oral cavity of a patient; an order form action, comprising selecting a specific type of treatment to be performed; a model retrieval action, comprising selecting and retrieving a stored 3D model from a database; a patient monitoring action, comprising comparing at least two dental scans taken at different times; a restorative action, comprising performing a digital design of at least one dental prosthesis; a treatment planning action, comprising generating at least one orthodontic target design of the jaws of a patient; a patient excitement action, comprising generating at least one digital image of an expected target oral situation of a patient; a record population action, comprising populating a digital patient record with new or updated information, for example, such as in a case of populating a patient's digital dental chart; an analyzer action, comprising analyzing the 3D scan of the oral cavity in relation to different dental parameters; and a practice management action, comprising managing and maintaining patent related administrative tasks. In accordance with an exemplary embodiment, an orthodontic target design may include one or 3D models representing patient's teeth in incrementally moved positions compared to an initial actual teeth arrangement of patient's teeth such that the one or 3D models correspond to teeth positions at different stages of an orthodontic treatment such as in case of digital designing of one or more models in a clear aligner treatment. In addition, for example, the scan model output may represent oral cavity of a patient such as an intra oral scan model.

In accordance with an exemplary embodiment, each the action output of the respective plurality of workflows is preceded with an action, and the action input and the action output of the respective plurality of workflow actions in the group comprising: the scanning action, comprising a scanner data action input and a scan model output; an intra oral scanning action, comprising an intra oral scanner data action input and an intra oral scan model output; an order form action, comprising an intra oral scan model and/or a treatment specification input and treatment basic data as an output; a patient monitoring action, comprising at least two scan models as action input and an animation and/or a difference map as an output; a restorative action, comprising treatment basic data as an input and a dental prosthesis design as an output; a treatment planning action, comprising treatment basic data as an input and a target oral situation as an output; a patient excitement action, comprising one or more patient specific data as input and an estimated result as an output; a record population action, comprising one or more patient specific clinical data (e.g. diagnostic data such as derived from 3D data and/or texture data, e.g. caries indication) as input and an updated record population file as an output; and a model retrieval action, analyzer action, and practice management action. In accordance with an exemplary embodiment, the clinical data may include diagnostic data such as derived from 3D data and/or texture data, for example, caries indication.

In accordance with an exemplary embodiment, the suggesting of at least the second workflow action and the third workflow action can include visually presenting the suggestions of the second workflow action and the third workflow action on a monitor subsequent to generating the action output of the first workflow action. For example, the visually presenting of the suggestions of the at least the second workflow action and the third workflow action can appear in response to a user initiated trigger event. The trigger event can be a user pressing a continue button, for example, the user makes a choice whether to see the generated suggestions. Alternatively, in accordance with an exemplary embodiment, the generated suggestions may always be presented. However, the user may choose to click complete, which would define end of the digital dental workflow.

In accordance with an exemplary embodiment, the method can further include performing an intra oral scan of a patient as the first workflow action or retrieving a stored previously generated model; and activating at least one of a patient monitoring workflow action or an order form workflow action as part of the digital dental workflow from the selected at least the second workflow action or the third workflow action.

In accordance with an exemplary embodiment, the method can further include providing a user interface for guiding a user through the digital dental workflow, the user interface comprises: the first action workflow, which when activated prompts the user to obtain an action output comprising a 3D scan model comprising 3D data of patient oral cavity with or without texture data; an intra oral scan action, which when activated prompts the user for an intra oral scan action and obtaining a 3D scan comprising 3D data and texture data; a history area in the user interface, wherein at least one 3D scan file is indexed; and wherein the user is prompted with a selection of at least an order form action or a patient monitoring action.

In accordance with an exemplary embodiment, the digital dental workflow can be for assisting a dental professional in a dental evaluation or treatment of a patient, and can further comprise: providing at least a digital representation data set at least partly based on the patient's oral situation as input into the digital dental workflow, and wherein the digital dental workflow comprises the first workflow action and one of the second workflow action or the third workflow action; verifying whether the digital representation data set can be used in the first workflow action and the one of the second workflow action or the third workflow action; and generating an alert if the verification of the digital representation data set fails in one or both of the first workflow action and the one of the second workflow action or the third workflow action. In accordance with an exemplary embodiment, verification may be against criteria set that is dependent on the workflow action to which the digital representation data set is to be provided as action input. For example, the criteria set may include one or more of generated 3D model property such as resolution or coverage defining which dental object is being represented in the 3D model, patient information, etc. In accordance with an exemplary embodiment, in response to the verification failing, one or more criteria that is not met can be indicated and/or which aspects need to be addressed can be recommended, for example, on the monitor to meet the missed criteria of the verification criteria set. In addition, the user may receive other suggested other workflow actions including the workflow action that generated the action output that failed the verification criteria, and wherein the user can fix the problem by using one of the workflow actions that can be suggested to fix the problem.

In addition, the verification of the digital representation data set for the first workflow action can be at least partly different from the verification of the digital representation data set for the one of the second workflow action or the third workflow action. In accordance with an exemplary embodiment, the method can further include visually representing in a user interface the first workflow action and the one of the second workflow action or the third workflow action as a first action button and a second action button, respectively, and wherein the first action button and the second action button are in a disabled state if the digital representation data set fails the verification.

In accordance with an exemplary embodiment, the selecting the at least the second workflow action or the third workflow action can include: selecting one or more digital datasets from a dataset library; providing a workflow action library comprising at least two workflow actions; wherein each workflow action comprises at least one dataset qualifier; and enabling one or more of the workflow actions to be selected by a user if the datasets selected from the dataset library passes the at least one dataset qualifier of the respective workflow.

In accordance with an exemplary embodiment, the method can further include obtaining a first intra oral scan of an oral cavity of a patient as action input for the first workflow action; generating a segmented data set in a form of a three-dimensional (3D) scan of the oral cavity of the patient from the intra oral scan as the action output from the action input of the first workflow action; detecting one or more of a restorative action or a treatment planning action for the patient based on the segmented data set in the form of the 3D can of the oral cavity using a machine learning based analysis and design algorithm as the at least second workflow action or the third workflow action; and suggesting at least another workflow action for at least one second intra oral scan of the oral cavity of the patient as action input for generating a second 3D scan of the oral cavity of the patient as action output for the restoration action or the treatment planning action detected by the machine learning based analysis and design algorithm.

In accordance with an exemplary embodiment, the method and system as disclosed herein can also include a patient monitoring feature that compares surface scans over time is an action that is available every time there are two surface scans representing at least the same portion of the patient's dental situation. After completing the patient monitoring workflow, for example, a new action can be chosen based on the findings from the patient monitoring. The new action could be creating a night guard in splint studio which thereafter is produced in-house or send to a lab.

In accordance with an exemplary embodiment, for example, for a new patient with no existing data. New patient is created in the system with no existing data. A treatment type/action is chosen from a list of actions available for that specific clinic. After choosing a treatment/action the system prompts the necessary data of the patient's dental situation. When the necessary data for the treatment/action type is acquired the system will initiate the digital process for the treatment. For example, a patient may need a new implant. When the surgeon/user/dentist selects Implant Studio the system will prompt the user to acquire/import a CBCT scan and surface scan. When the data is in the system and is verified to be sufficient, for example, an implant studio can be shown on the graphical user interface, and the user can design a surgical guide which later can be printed in-house or send to a lab.

In accordance with an exemplary embodiment, for example, two cases for a new patient that needs a new implant can include:
(1) The user selects a treatment/action which automatically goes through the existing data on the patient. If any of the data can be used in the chosen treatment/action it is displayed for the user. Before the data is displayed for the user the system runs through a list of verification criteria that consists of the quality, size, the content of the data and what is needed for the selected treatment/action; or
(2) If none of the existing data qualifies to be used for the treatment/action the user is prompted to acquire data or import it to the platform/system if it exists outside the system. The data needed is presented by the system and the user can directly start a scan that is needed.

In accordance with an exemplary embodiment, the number of different actions that can be initially chosen are not restricted or limited, however, as a new action is chosen the number of actions that are applicable are based on the first action and a technical outcome and the professional decision of the user/orthodontic/dentist of how to proceed for the specific patient. In addition, the course of the patient's case can be, for example, be finalized by the creation of a physical appliance either in-house or sent to a lab or when there are no applicable cases for the patient.

In accordance with an exemplary embodiment, the data can be organized by patient names comprising of all cases for each patient displayed according to the date they were created, or alternatively in alphabetic order. In addition, as disclosed herein, one or more dental treatments may need more than one visit at the dentist. For example, a clear aligner treatment where continuous appointments are made for the dentist to track the progress of the patient. However, without a digital dental workflow, it is expected by the dentist to quantify the movement of the teeth since the last appointment. For example, the method and system as disclosed herein can create a digital dental workflow that automatically compares the current dental situation with the relevant stage from the treatment plan.

In accordance with an exemplary embodiment, the method and system as disclosed herein can be used with third (3rd) party websites with dental workflows/actions that are available outside of the digital dental system are integrated into the system creating a single entry for all dental workflows in a single system. For example, by having all relevant websites and application in a single system the user can rather easily handle all patient data and upload it to the desired workflows without having to export files to their local drive before sending it out. The system can also display notifications from the 3^{rd} party applications and website. For example, when an action is chosen the input data representing a patient a verification process automatically initiated. The input data is analyzed and verified based on the input requirements for the action/workflow which is chosen. An example of criteria for a validations process to begin a clear aligner treatment may be a full surface scan of both upper and lower jaw and an x-ray scan of the patient, which could be a cephalometric or CBCT scan. The x-ray could be an optional requirement while the surface scans are a minimum to start the clear aligner treatment action.

In accordance with an exemplary embodiment, when creating a new case for a patient the user can choose between proposed workflows that are predefined for a specific dental treatment or between independent actions. For example, a predefined workflow could be a clear aligner treatment where specific independent actions are executed in a specific order. When choosing a workflow, the user will therefore be guided through the treatment in the most optimal way. The different independent actions that a workflow consists of will be compiled and shown in a history timeline. Future actions that relates to a treatment workflow will be saved in the already existing compiled workflow, which can help create an easy overview between the actions related to a specific treatment workflow and the independent actions for each patient. In addition, when a predefined workflow or an independent action is executed a list of proposed new actions and workflows will be displayed, which is based on the output from the previously finished action.

In addition, as disclosed herein, independent actions can be performed, for example, a surface scan, or an x-ray scan. A predefined workflow, for example, for clear aligners would consist of a surface scan and a clear aligner action. The method and system as disclosed also enables relatively easy and convenient access to third party services, organizes all created digital dental data of the patient and collects all communication between user/orthodontist/dentist with the lab and other third-party services, and which creates a single access point for the user compiling all aspects of a digital dental workflow.

In accordance with an exemplary embodiment, the method and system as disclosed herein can decompose the static workflows into sub-components, which sub-components can be used in a more dynamic network. For example, a sub-workflow component may require a specific input and deliver a specific output which may be used as a new input for another sub-component. Thus, for example, a Trios design studio (a software module where the dentist can design a crown) will require a 3D model as input (generated from an intraoral scanner) and generate a CAD file (e.g. STL file) of a crown as an output, which output may be used in a CAM software module to produce the physical component. For example, a patient may enter a clinic with a problem with one incisor. If the correct treatment should be a crown or a veneer is unclear before prepping the tooth is initiated. The action based workflow allows the dentist to postpone the decision within the software until the appropriate time. Alternatively, a patient need two restorations done, for example, one molar which should be an in-house fabrication and one pre-molar which need to be made by a lab for aesthetic reasons. The dentist may first agree with the patient that both teeth should be made with E-MAX. During treatment and preparation, the dentist realize that there is probably a need for a higher level of aesthetics, and suggests the patient to make one of the restoration in a different material, and with a different production method (stained and glazed). The dentist must agree on a new price with the patient, change the restoration parameters, and may need to send the order to a different dental laboratories (because the other lab mainly produces E-MAX molars)

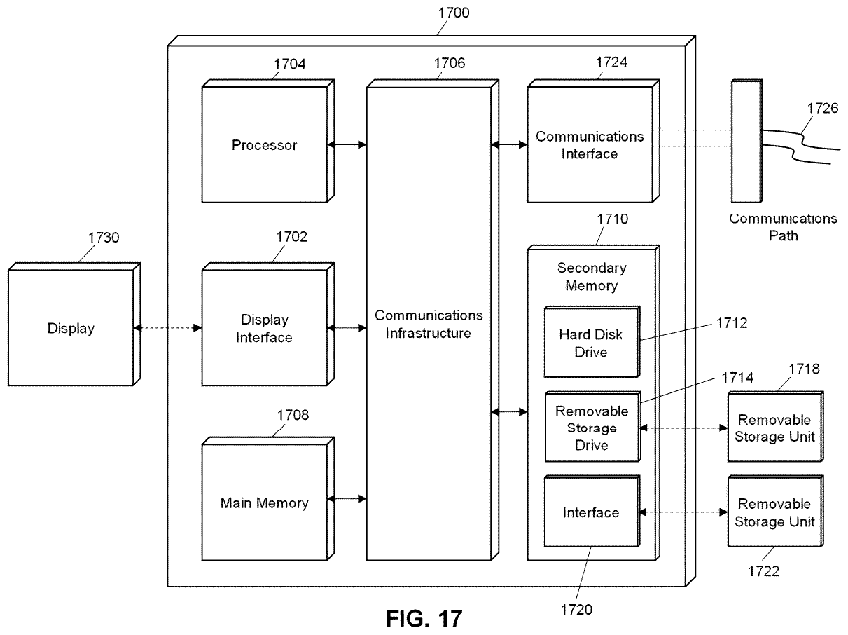

FIG. 17 illustrates a representative computer system 1700 in which embodiments of the present disclosure, or portions thereof, may be implemented as computer-readable code executed on a processor of a computer. For example, the system and methods as disclosed in FIGS. 1-16 may be implemented in whole or in part by a computer system 1700 using hardware, software executed on hardware, firmware, non-transitory computer readable media having instructions stored thereon, or a combination thereof and may be implemented in one or more computer systems or other processing systems. Hardware, software executed on hardware, or any combination thereof may embody modules and components used to implement the methods and steps of the present disclosure.

If programmable logic is used, such logic may execute on a commercially available processing platform configured by executable software code to become a specific purpose computer or a special purpose device (for example, programmable logic array, application-specific integrated circuit, etc.). A person having ordinary skill in the art may appreciate that embodiments of the disclosed subject matter can be practiced with various computer system configurations, including multi-core multiprocessor systems, minicomputers, mainframe computers, computers linked or clustered with distributed functions, as well as pervasive or miniature computers that may be embedded into virtually any device. For instance, at least one processor device and a memory may be used to implement the above described embodiments.

A processor unit or device as discussed herein may be a single processor, a plurality of processors, or combinations thereof. Processor devices may have one or more processor “cores.” The terms “computer program medium,” “non-transitory computer readable medium,” and “computer usable medium” as discussed herein are used to generally refer to tangible media such as a removable storage unit 1718, a removable storage unit 1722, and a hard disk installed in hard disk drive 1712.

Various embodiments of the present disclosure are described in terms of this representative computer system 1700. After reading this description, it will become apparent to a person skilled in the relevant art how to implement the present disclosure using other computer systems and/or computer architectures. Although operations may be described as a sequential process, some of the operations may in fact be performed in parallel, concurrently, and/or in a distributed environment, and with program code stored locally or remotely for access by single or multi-processor machines. In addition, in some embodiments the order of operations may be rearranged without departing from the spirit of the disclosed subject matter.

Processor device 1704 may be a special purpose or a general purpose processor device specifically configured to perform the functions discussed herein. The processor device 1704 may be connected to a communications infrastructure 1706, such as a bus, message queue, network, multi-core message-passing scheme, etc. The network may be any network suitable for performing the functions as disclosed herein and may include a local area network (“LAN”), a wide area network (“WAN”), a wireless network (e.g., “Wi-Fi”), a mobile communication network, a satellite network, the Internet, fiber optic, coaxial cable, infrared, radio frequency (“RF”), or any combination thereof. Other suitable network types and configurations will be apparent to persons having skill in the relevant art. The computer system 1700 may also include a main memory 1708 (e.g., random access memory, read-only memory, etc.), and may also include a secondary memory 1710. The secondary memory 1710 may include the hard disk drive 1712 and a removable storage drive 1714, such as a floppy disk drive, a magnetic tape drive, an optical disk drive, a flash memory, etc.

The removable storage drive 1714 may read from and/or write to the removable storage unit 1718 in a well-known manner. The removable storage unit 1718 may include a removable storage media that may be read by and written to by the removable storage drive 1714. For example, if the removable storage drive 1714 is a floppy disk drive or universal serial bus port, the removable storage unit 1718 may be a floppy disk or portable flash drive, respectively. In one embodiment, the removable storage unit 1718 may be non-transitory computer readable recording media.

In some embodiments, the secondary memory 1710 may include alternative means for allowing computer programs or other instructions to be loaded into the computer system 1700, for example, the removable storage unit 1722 and an interface 1720. Examples of such means may include a program cartridge and cartridge interface (e.g., as found in video game systems), a removable memory chip (e.g., EEPROM, PROM, etc.) and associated socket, and other removable storage units 1722 and interfaces 1720 as will be apparent to persons having skill in the relevant art.

Data stored in the computer system 1700 (e.g., in the main memory 1708 and/or the secondary memory 1710) may be stored on any type of suitable computer readable media, such as optical storage (e.g., a compact disc, digital versatile disc, Blu-ray disc, etc.) or magnetic tape storage (e.g., a hard disk drive). The data may be configured in any type of suitable database configuration, such as a relational database, a structured query language (SQL) database, a distributed database, an object database, etc. Suitable configurations and storage types will be apparent to persons having skill in the relevant art.

The computer system 1700 may also include a communications interface 1724. The communications interface 1724 may be configured to allow software and data to be transferred between the computer system 1700 and external devices. Exemplary communications interfaces 1724 may include a modem, a network interface (e.g., an Ethernet card), a communications port, a PCMCIA slot and card, etc. Software and data transferred via the communications interface 1724 may be in the form of signals, which may be electronic, electromagnetic, optical, or other signals as will be apparent to persons having skill in the relevant art. The signals may travel via a communications path 1726, which may be configured to carry the signals and may be implemented using wire, cable, fiber optics, a phone line, a cellular phone link, a radio frequency link, etc.

The computer system 1700 may further include a display interface 1702. The display interface 1702 may be configured to allow data to be transferred between the computer system 1700 and external display 1730. Exemplary display interfaces 1702 may include high-definition multimedia interface (HDMI), digital visual interface (DVI), video graphics array (VGA), etc. The display 630 may be any suitable type of display for displaying data transmitted via the display interface 1702 of the computer system 1700, including a cathode ray tube (CRT) display, liquid crystal display (LCD), light-emitting diode (LED) display, capacitive touch display, thin-film transistor (TFT) display, etc.

Computer program medium and computer usable medium may refer to memories, such as the main memory 1708 and secondary memory 1710, which may be memory semiconductors (e.g., DRAMs, etc.). These computer program products may be means for providing software to the computer system 1700. Computer programs (e.g., computer control logic) may be stored in the main memory 1708 and/or the secondary memory 1710. Computer programs may also be received via the communications interface 1724. Such computer programs, when executed, may enable computer system 1700 to implement the present methods as discussed herein. In particular, the computer programs, when executed, may enable processor device 1704 to implement the methods illustrated by FIGS. 1-5, as discussed herein. Accordingly, such computer programs may represent controllers of the computer system 1700. Where the present disclosure is implemented using software executed on hardware, the software may be stored in a computer program product and loaded into the computer system 1700 using the removable storage drive 1714, interface 1720, and hard disk drive 1712, or communications interface 1724.

The processor device 1704 may comprise one or more modules or engines configured to perform the functions of the computer system 1700. Each of the modules or engines may be implemented using hardware and, in some instances, may also utilize software executed on hardware, such as corresponding to program code and/or programs stored in the main memory 1708 or secondary memory 1710. In such instances, program code may be compiled by the processor device 1704 (e.g., by a compiling module or engine) prior to execution by the hardware of the computer system 1700. For example, the program code may be source code written in a programming language that is translated into a lower level language, such as assembly language or machine code, for execution by the processor device 1704 and/or any additional hardware components of the computer system 1700. The process of compiling may include the use of lexical analysis, preprocessing, parsing, semantic analysis, syntax-directed translation, code generation, code optimization, and any other techniques that may be suitable for translation of program code into a lower level language suitable for controlling the computer system 1700 to perform the functions disclosed herein. It will be apparent to persons having skill in the relevant art that such processes result in the computer system 1700 being a specially configured computer system 1700 uniquely programmed to perform the functions discussed above.

For example, the computer system 1700 can be used for assisting a dental professional in a dental evaluation or treatment of a patient, wherein the system 1700 comprises: a computer system comprising a processor and a computer readable medium comprising executable instructions, which when executed by the processor: receive a first workflow action selected from a plurality of workflow actions, the first workflow action including an action input; generate an action output at least partly based on the action input of the first workflow action; suggest at least a second workflow action and a third workflow action from the plurality of workflow actions based on the action output generated by the first workflow action, wherein at least a part of the action output of the first workflow action at least partly represents an action input for each of the at least the second workflow action and the third workflow action; and generate the digital dental workflow upon a selection of the at least the second workflow action or the third workflow action, and wherein the generated digital dental workflow comprises the first workflow and the selected at least the second workflow action or third workflow action.

In addition, a computer program product embodied in a non-transitory computer readable medium, the computer program product comprising computer readable program code being executable by a hardware data processor to cause the hardware data processor to provide instructions for generating a digital dental workflow, the instructions comprising: receiving a first workflow action selected from a plurality of workflow actions, the first workflow action including an action input; generating an action output at least partly based on the action input of the first workflow action; suggesting at least a second workflow action and a third workflow action from the plurality of workflow actions based on the action output generated by the first workflow action, wherein at least a part of the action output of the first workflow action at least partly represents an action input for each of the at least the second workflow action and the third workflow action; and generating the digital dental workflow upon a selection of the at least the second workflow action or the third workflow action, and wherein the generated digital dental workflow comprises the first workflow and the selected at least the second workflow action or third workflow action.

Although some embodiments have been described and shown in detail, the invention is not restricted to them, but may also be embodied in other ways within the scope of the subject matter defined in the following claims. In particular, it is to be understood that other embodiments may be utilized and structural and functional modifications may be made without departing from the scope of the present invention.

In device claims enumerating several means, several of these means can be embodied by one and the same item of hardware. The mere fact that certain measures are recited in mutually different dependent claims or described in different embodiments does not indicate that a combination of these measures cannot be used to advantage.

A claim may refer to any of the preceding claims, and “any” is understood to mean “any one or more” of the preceding claims.

The term “obtaining” as used in this specification may refer to physically acquiring for example medical images using a medical imaging device, but it may also refer for example to loading into a computer an image or a digital representation previously acquired.

It should be emphasized that the term “comprises/comprising” when used in this specification is taken to specify the presence of stated features, integers, steps or components but does not preclude the presence or addition of one or more other features, integers, steps, components or groups thereof.

The features of the method described above and in the following may be implemented in software and carried out on a data processing system or other processing means caused by the execution of computer-executable instructions. The instructions may be program code means loaded in a memory, such as a RAM, from a storage medium or from another computer via a computer network. Alternatively, the described features may be implemented by hardwired circuitry instead of software or in combination with software.

The detailed description above describes embodiments of a method and system for action based workflow and more particularly to a method and system for dynamically generating a digital dental flow comprising at least two workflows. The invention is not limited, however, to the precise embodiments and variations described. Various changes, modifications and equivalents may occur to one skilled in the art without departing from the spirit and scope of the invention as defined in the

### List of Items

1. A computer-implemented method for generating a digital dental workflow, the method comprising:
   receiving a first workflow action selected from a plurality of workflow actions, the first workflow action including an action input;
   generating an action output at least partly based on the action input of the first workflow action;
   suggesting at least a second workflow action and a third workflow action from the plurality of workflow actions based on the action output generated by the first workflow action, wherein at least a part of the action output of the first workflow action at least partly represents an action input for each of the at least the second workflow action and the third workflow action; and
   generating the digital dental workflow upon a selection of the at least the second workflow action or the third workflow action, and wherein the generated digital dental workflow comprises the first workflow and the selected at least the second workflow action or third workflow action.
2. The computer-implemented method according to item 1, further comprising:
   obtaining a first intra oral scan of an oral cavity of a patient as action input for the first workflow action;
   generating a three-dimensional (3D) scan of the oral cavity of the patient from the intra oral scan as the action output from the action input of the first workflow action or selecting and retrieving a stored previously generated model; and
   suggesting a predefined workflow as the at least the second workflow action and the third workflow action.
3. The computer-implemented method according to any of the preceding items, further comprising:
   suggesting, after the selecting of the the at least the second workflow action and the third workflow action, at least another workflow action for one second intra oral scan of the oral cavity as action input for generating a second 3D scan of the oral cavity of the patient; and
   digitally designing a dental prosthesis based on the second 3D scan.
4. The computer-implemented method according to any of the preceding items, wherein the plurality of workflow actions are chosen from a group consisting of:
   a scanning action, comprising scanning a dental object or a gypsum model;
   an intra oral scanning action, comprising scanning directly in an oral cavity of a patient;
   an order form action, comprising selecting a specific type of treatment to be performed;
   a model retrieval action, comprising selecting and retrieving a stored 3D model from a database;
   a patient monitoring action, comprising comparing at least two dental scans taken at different times;
   a restorative action, comprising performing a digital design of at least one dental prosthesis;
   a treatment planning action, comprising generating at least one orthodontic target design of the jaws of a patient;
   a patient excitement action, comprising generating at least one digital image of an expected target oral situation of a patient;
   a record population action, comprising populating a digital patient record with new or updated information;
   an analyzer action, comprising analyzing the 3D scan of the oral cavity in relation to different dental parameters; and
   a practice management action, comprising managing and maintaining patent related administrative tasks.
5. The computer-implemented method according to any of the preceding items, wherein each the action output of the respective plurality of workflows is preceded with an action, and the action input and the action output of the respective plurality of workflow actions in the group comprising:
   the scanning action, comprising a scanner data action input and a scan model output;
   an intra oral scanning action, comprising an intra oral scanner data action input and an intra oral scan model output;
   an order form action, comprising, an intra oral scan model and/or a treatment specification input and treatment basic data as an output;
   a patient monitoring action, comprising at least two scan models as action input and an animation and/or a difference map as an output;
   a restorative action, comprising treatment basic data as an input and a dental prosthesis design as an output;
   a treatment planning action, comprising treatment basic data as an input and a target oral situation as an output;
   a patient excitement action, comprising one or more patient specific data as input and an estimated result as an output;
   a record population action, comprising one or more patient specific clinical data as input and an updated record population file as an output; and a model retrieval action, analyzer action, and practice management action.
6. The computer-implemented method according to any of the preceding items, wherein the suggesting of at least the second workflow action and the third workflow action comprises visually presenting the suggestions of the second workflow action and the third workflow action on a monitor subsequent to generating the action output of the first workflow action.
7. The computer-implemented method according to any of the preceding items, wherein the visually presenting of the suggestions of the at least the second workflow action and the third workflow action appears in response to a user initiated trigger event.
8. The computer-implemented method according to any of the preceding items, further comprising:
   performing an intra oral scan of a patient as the first workflow action or retrieving a stored previously generated model; and
   activating at least one of a patient monitoring workflow action or an order form workflow action as part of the digital dental workflow from the selected at least the second workflow action or the third workflow action.
9. The computer-implemented method according to any of the preceding items, further comprising:
   providing a user interface for guiding a user through the digital dental workflow, the user interface comprises:
      the first action workflow, which when activated prompts the user to obtain an action output comprising a 3D scan model comprising 3D data of patient oral cavity with or without texture data;
      an intra oral scan action, which when activated prompts the user for an intra oral scan action and obtaining a 3D scan comprising 3D data and texture data;
      a history area in the user interface, wherein at least one 3D scan file is indexed; and
      wherein the user is prompted with a selection of at least an order form action or a patient monitoring action.
10. The computer-implemented method according to any of the preceding items, wherein the digital dental workflow is for assisting a dental professional in a dental evaluation or treatment of a patient, and further comprise:
   providing at least a digital representation data set at least a partly based on the patient's oral situation as input into the digital dental workflow, and wherein the digital dental workflow comprises the first workflow action and one of the second workflow action or the third workflow action;
   verifying whether the digital representation data set can be used in the first workflow action and the one of the second workflow action or the third workflow action; and
   generating an alert if the verification of the digital representation data set fails in one or both of the first workflow action and the one of the second workflow action or the third workflow action.
11. The computer-implemented method according to any of the preceding items, wherein the verification of the digital representation data set for the first workflow action is at least partly different from the verification of the digital representation data set for the one of the second workflow action or the third workflow action.
12. The computer-implemented method according to any of the preceding items, further comprising:
   visually representing in a user interface the first workflow action and the one of the second workflow action or the third workflow action as a first action button and a second action button, respectively, and wherein the first action button and the second action button are in a disabled state if the digital representation data set fails the verification.
13. The computer-implemented method according to any of the preceding items, wherein the selecting the at least the second workflow action or the third workflow action comprises:
   selecting one or more digital datasets from a dataset library;
   providing a workflow action library comprising at least two workflow actions;
   wherein each workflow action comprises at least one dataset qualifier; and
   enabling one or more of the workflow actions to be selected by a user if the datasets selected from the dataset library passes the at least one dataset qualifier of the respective workflow.
14. The computer-implemented method according to any of the preceding items, further comprising:
   obtaining a first intra oral scan of an oral cavity of a patient as action input for the first workflow action;
   generating a segmented data set in a form of a three-dimensional (3D) scan of the oral cavity of the patient from the intra oral scan as the action output from the action input of the first workflow action;
   detecting one or more of a restorative action or a treatment planning action for the patient based on the segmented data set in the form of the 3D can of the oral cavity using a machine learning based analysis and design algorithm as the at least second workflow action or the third workflow action; and
   suggesting at least another workflow action for at least one second intra oral scan of the oral cavity of the patient as action input for generating a second 3D scan of the oral cavity of the patient as action output for the restoration action or the treatment planning action detected by the machine learning based analysis and design algorithm.
15. A system for assisting a dental professional in a dental evaluation or treatment of a patient, wherein the system comprises:
   a computer system comprising a processor and a computer readable medium comprising executable instructions, which when executed by the processor:
      receive a first workflow action selected from a plurality of workflow actions, the first workflow action including an action input;
      generate an action output at least partly based on the action input of the first workflow action;
      suggest at least a second workflow action and a third workflow action from the plurality of workflow actions based on the action output generated by the first workflow action, wherein at least a part of the action output of the first workflow action at least partly represents an action input for each of the at least the second workflow action and the third workflow action; and
      generate the digital dental workflow upon a selection of the at least the second workflow action or the third workflow action, and wherein the generated digital dental workflow comprises the first workflow and the selected at least the second workflow action or third workflow action.
16. A system for assisting a dental professional in a dental evaluation or treatment of a patient, wherein the system comprises:
   an intra oral scanner; and
   a computer system in communication with the intra oral scanner for generating a digital dental workflow, the computer system include a processor configured to:
      receive a first workflow action selected from a plurality of workflow actions, the first workflow action including an action input;
      generate an action output from the action input of the first workflow action;
      suggest at least a second workflow action and a third workflow action from the plurality of workflow actions based on the action output generated by the first workflow action, wherein at least a part of the action output of the first workflow action includes an action input for each of the at least the second workflow action and the third workflow action; and
      generate the digital dental workflow upon a selection of the at least the second workflow action or the third workflow action.
17. The system according to any of the preceding items 15 to 16, further comprising:
   an intra oral scanner in communication with the computer system, the intra oral scanner configured to obtain a first intra oral scan of an oral cavity of a patient as action input for the first workflow action; and
   the processor further configured to:
      generate a three-dimensional (3D) scan of the oral cavity of the patient from the intra oral scan as the action output from the action input of the first workflow action or select and retrieve a stored previously generated model; and
      suggest a predefined workflow as the at least the second workflow action and the third workflow action.
18. The system according to any of the preceding items 15 to 17, wherein the processor is further configured to:
   suggest, after the selecting of the the at least the second workflow action and the third workflow action, at least another workflow action for one second intra oral scan of the oral cavity as action input for generating a second 3D scan of the oral cavity of the patient; and
   digitally design a dental prosthesis based on the second 3D scan.
19. The system according to any of the preceding items 15 to 18, wherein the plurality of workflow actions are chosen from a group consisting of:
   a scanning action, comprising scanning a dental object or a gypsum model;
   an intra oral scanning action, comprising scanning directly in an oral cavity of a patient;
   an order form action, comprising selecting a specific type of treatment to be performed;
   a model retrieval action, comprising selecting and retrieving a stored 3D model from a database;
   a patient monitoring action, comprising comparing at least two dental scans taken at different times;
   a restorative action, comprising performing a digital design of at least one dental prosthesis;
   a treatment planning action, comprising generating at least one orthodontic target design of the jaws of a patient;
   a patient excitement action, comprising generating at least one digital image of an expected target oral situation of a patient;
   a record population action, comprising populating a digital patient record with new or updated information;
   an analyzer action, comprising analyzing the 3D scan of the oral cavity in relation to different dental parameters; and a
   practice management action, comprising managing and maintaining patent related administrative tasks.
20. The system according to any of the preceding items 15 to 19, wherein each the action output of the respective plurality of workflows is preceded with an action, and the action input and the action output of the respective plurality of workflow actions in the group comprising:
   the scanning action, comprising a scanner data action input and a scan model output;
   an intra oral scanning action, comprising an intra oral scanner data action input and an intra oral scan model output;
   an order form action, comprising, an intra oral scan model and/or a treatment specification input and treatment basic data as an output;
   a patient monitoring action, comprising at least two scan models as action input and an animation and/or a difference map as an output;
   a restorative action, comprising treatment basic data as an input and a dental prosthesis design as an output;
   a treatment planning action, comprising treatment basic data as an input and a target oral situation as an output;
   a patient excitement action, comprising one or more patient specific data as input and an estimated result as an output;
   a record population action, comprising one or more patient specific clinical data as input and an updated record population file as an output; and
   a model retrieval action, analyzer action, and practice management action.
21. The system according to any of the preceding items 15 to 20, wherein the processor is further configured to perform one or more steps of method claims 1 to 14.
22. A computer program product embodied in a non-transitory computer readable medium, the computer program product comprising computer readable program code being executable by a hardware data processor to cause the hardware data processor to provide instructions for generating a digital dental workflow, the instructions comprising:
   receiving a first workflow action selected from a plurality of workflow actions, the first workflow action including an action input;
   generating an action output at least partly based on the action input of the first workflow action;
   suggesting at least a second workflow action and a third workflow action from the plurality of workflow actions based on the action output generated by the first workflow action, wherein at least a part of the action output of the first workflow action at least partly represents an action input for each of the at least the second workflow action and the third workflow action; and
   generating the digital dental workflow upon a selection of the at least the second workflow action or the third workflow action, and wherein the generated digital dental workflow comprises the first workflow and the selected at least the second workflow action or third workflow action.
23. The system according to item 22, wherein the processor is further configured to perform one or more steps of method claims 1 to 14.

What is claimed is:

1. A computer-implemented method for generating a digital dental workflow, the method comprising:
receiving a first workflow action selected from a plurality of workflow actions, the first workflow action including an action input;
generating an action output at least partly based on the action input of the first workflow action;
suggesting at least a second workflow action and a third workflow action from the plurality of workflow actions based on the action output generated by the first workflow action, wherein at least a part of the action output of the first workflow action at least partly represents an action input for each of the at least the second workflow action and the third workflow action; and
generating the digital dental workflow upon a selection of the at least the second workflow action or the third workflow action, and wherein the generated digital dental workflow comprises the first workflow and the selected at least the second workflow action or third workflow action.

2. The computer-implemented method according to claim 1, further comprising:
obtaining a first intra oral scan of an oral cavity of a patient as action input for the first workflow action;
generating a three-dimensional (3D) scan of the oral cavity of the patient from the intra oral scan as the action output from the action input of the first workflow action or selecting and retrieving a stored previously generated model; and
suggesting a predefined workflow as the at least the second workflow action and the third workflow action.

3. The computer-implemented method according to claim 2, further comprising:
suggesting, after the selecting of the the at least the second workflow action and the third workflow action, at least another workflow action for one second intra oral scan of the oral cavity as action input for generating a second 3D scan of the oral cavity of the patient; and
digitally designing a dental prosthesis based on the second 3D scan.

4. The computer-implemented method according to claim 1, wherein the plurality of workflow actions are chosen from a group consisting of:
a scanning action, comprising scanning a dental object or a gypsum model;
an intra oral scanning action, comprising scanning directly in an oral cavity of a patient;
an order form action, comprising selecting a specific type of treatment to be performed;
a model retrieval action, comprising selecting and retrieving a stored 3D model from a database;
a patient monitoring action, comprising comparing at least two dental scans taken at different times;
a restorative action, comprising performing a digital design of at least one dental prosthesis;
a treatment planning action, comprising generating at least one orthodontic target design of the jaws of a patient;
a patient excitement action, comprising generating at least one digital image of an expected target oral situation of a patient;
a record population action, comprising populating a digital patient record with new or updated information;
an analyzer action, comprising analyzing the 3D scan of the oral cavity in relation to different dental parameters; and
a practice management action, comprising managing and maintaining patent related administrative tasks.

5. The computer-implemented method according to claim 4, wherein each the action output of the respective plurality of workflows is preceded with an action, and the action input and the action output of the respective plurality of workflow actions in the group comprising:
the scanning action, comprising a scanner data action input and a scan model output;
an intra oral scanning action, comprising an intra oral scanner data action input and an intra oral scan model output;
an order form action, comprising, an intra oral scan model and/or a treatment specification input and treatment basic data as an output;
a patient monitoring action, comprising at least two scan models as action input and an animation and/or a difference map as an output;
a restorative action, comprising treatment basic data as an input and a dental prosthesis design as an output;
a treatment planning action, comprising treatment basic data as an input and a target oral situation as an output;
a patient excitement action, comprising one or more patient specific data as input and an estimated result as an output;
a record population action, comprising one or more patient specific clinical data as input and an updated record population file as an output; and
a model retrieval action, analyzer action, and practice management action.

6. The computer-implemented method according to claim 1, wherein the suggesting of at least the second workflow action and the third workflow action comprises visually presenting the suggestions of the second workflow action and the third workflow action on a monitor subsequent to generating the action output of the first workflow action.

7. The computer-implemented method according to claim 6, wherein the visually presenting of the suggestions of the at least the second workflow action and the third workflow action appears in response to a user initiated trigger event.

8. The computer-implemented method according to claim 1, further comprising:
performing an intra oral scan of a patient as the first workflow action or retrieving a stored previously generated model; and
activating at least one of a patient monitoring workflow action or an order form workflow action as part of the digital dental workflow from the selected at least the second workflow action or the third workflow action.

9. The computer-implemented method according to claim 1, further comprising:
providing a user interface for guiding a user through the digital dental workflow, the user interface comprises:
the first action workflow, which when activated prompts the user to obtain an action output comprising a 3D scan model comprising 3D data of patient oral cavity with or without texture data;
an intra oral scan action, which when activated prompts the user for an intra oral scan action and obtaining a 3D scan comprising 3D data and texture data;
a history area in the user interface, wherein at least one 3D scan file is indexed; and
wherein the user is prompted with a selection of at least an order form action or a patient monitoring action.

10. The computer-implemented method according to claim 1, wherein the digital dental workflow is for assisting a dental professional in a dental evaluation or treatment of a patient, and further comprise:
providing at least a digital representation data set at least a partly based on the patient's oral situation as input into the digital dental workflow, and wherein the digital dental workflow comprises the first workflow action and one of the second workflow action or the third workflow action;
verifying whether the digital representation data set can be used in the first workflow action and the one of the second workflow action or the third workflow action; and
generating an alert if the verification of the digital representation data set fails in one or both of the first workflow action and the one of the second workflow action or the third workflow action.

11. The computer-implemented method according to claim 1, wherein the selecting the at least the second workflow action or the third workflow action comprises:
selecting one or more digital datasets from a dataset library;
providing a workflow action library comprising at least two workflow actions;
wherein each workflow action comprises at least one dataset qualifier; and
enabling one or more of the workflow actions to be selected by a user if the datasets selected from the dataset library passes the at least one dataset qualifier of the respective workflow.

12. The computer-implemented method according to claim 1, further comprising:
obtaining a first intra oral scan of an oral cavity of a patient as action input for the first workflow action;
generating a segmented data set in a form of a three-dimensional (3D) scan of the oral cavity of the patient from the intra oral scan as the action output from the action input of the first workflow action;
detecting one or more of a restorative action or a treatment planning action for the patient based on the segmented data set in the form of the 3D can of the oral cavity using a machine learning based analysis and design algorithm as the at least second workflow action or the third workflow action; and
suggesting at least another workflow action for at least one second intra oral scan of the oral cavity of the patient as action input for generating a second 3D scan of the oral cavity of the patient as action output for the restoration action or the treatment planning action detected by the machine learning based analysis and design algorithm.
